(19) United States
(12) Patent Application Publication
(10) Pub. No.: US 2026/0255877 A1
(43) Pub. Date: Aug. 27, 2026

(54) METHOD FOR MANUFACTURING AN ELASTIC SURFACE WAVE DEVICE

(71) Applicant: Soitec, BERNIN (FR)

(72) Inventors: Sylvain Ballandras, BERNIN (FR); Thierry Laroche, BERNIN (FR); Florent Bernard, BERNIN (FR); Emilie Courjon, BERNIN (FR); Saly N'Diaye, BERNIN (FR); Isabelle Huyet, BERNIN (FR)

(21) Appl. No.: 18/870,706

(22) PCT Filed: May 23, 2023
(86) PCT No.: PCT/EP2023/063810

§ 371 Date: Dec. 2, 2024

(30) Foreign Application Priority Data
Jun. 2, 2022 (FR) FR2205311
Jun. 2, 2022 (FR) FR2205312
Jun. 2, 2022 (FR) FR2205313

(51) Int. Cl. H10N 30/05

(52) U.S. Cl. CPC H10N 30/05

(57) ABSTRACT

A method is used for manufacturing an elastic wave device configured to operate at a frequency lower than 1 GHz, and formed on a POI substrate. The formation of the POI substrate comprises the following steps: —a) a step of implanting species in a LiTaO₃ substrate so as to form a useful layer; and —b) a step of transferring the useful layer onto a front face of a support substrate. The method further comprises the formation of an intermediate stack, positioned between the front face and the useful layer, and comprising, starting from the front face, a first layer, a second layer and a third layer, the first layer comprising silicon dioxide, the second layer comprising silicon nitride, alumina or aluminum nitride, and the third layer comprising silicon dioxide or amorphous silicon.

### CROSS-REFERENCE TO RELATED APPLICATIONS

This application is a national phase entry under 35 U.S.C. § 371 of International Patent Application PCT/EP2023/063810, filed May 23, 2023, designating the United States of America and published as International Patent Publication WO 2023/232562 A1 on Dec. 7, 2023, which claims the benefit under Article 8 of the Patent Cooperation Treaty of French Patent Application Serial Nos. FR2205311, FR2205312, and FR2205313, each of which was filed Jun. 2, 2022.

### TECHNICAL FIELD

The present disclosure relates to the field of elastic surface wave devices. More particularly, the present disclosure relates to a method of manufacturing an elastic surface wave device formed from a POI substrate that includes a layer of piezoelectric material.

### BACKGROUND

Originally manufactured on solid substrates of single-crystal piezoelectric materials (hereinafter “solid substrate”), surface acoustic wave filters (hereinafter “SAW filter” or “Surface Acoustic Wave filter”) now use piezoelectric substrates on insulator (hereinafter “POI”). These include, from front to back, a layer of piezoelectric material, a layer of dielectric material and a support substrate.

These POI substrates, unlike solid substrates, meet certain requirements in terms of the temperature sensitivity of the guided surface elastic modes in the piezoelectric material layer.

In particular, the support substrate acts as a stiffener, limiting thermal expansion and influencing the thermoelastic behavior of the piezoelectric material layer.

Generally speaking, a surface elastic mode propagating on a POI substrate, from which an elastic surface wave device is formed, has a relatively low temperature coefficient of frequency (TCF), notably less than 10 ppm·K⁻¹, in a frequency range extending from 1.4 GHz to 2.4 GHz.

The manufacture of POI substrates can implement a so-called “SmartCut™” process well known in the field of microelectronics, particularly for the manufacture of silicon-on-insulator substrates.

In this respect, the document [1] cited at the end of the description proposes transferring a layer of piezoelectric material and, more particularly, LiNbO₃ (hereinafter “LNO”), onto a silicon substrate using the SmartCut™ process.

The document [2] cited at the end of the description also discloses the use of a POI substrate exploiting a LiTaO₃ layer for the manufacture of an elastic surface wave filter. The elastic surface wave filter described herein comprises a lithium tantalate film on a mirror layer formed of alternating low acoustic impedance layers and high acoustic impedance layers on a silicon substrate.

It was also considered to insert a so-called trapping layer, for example, made of polycrystalline silicon, between the support substrate and the layer of dielectric material, and intended to limit the mean free path of charges at the interfaces of the stack as well as the crosstalk likely to occur within a filter formed from the POI substrate in question.

The advantages of the SmartCut™ process for forming a POI substrate are well known. In particular, the SmartCut™ process enables the removal of a layer of piezoelectric material, of controlled thickness, from a solid substrate of piezoelectric material known as a donor substrate. Furthermore, once recycled, the donor substrate can be used again to form other POI substrates. This last aspect makes the SmartCut™ process competitive.

POI substrates, thus capable of being formed using the SmartCut™ process, are typically implemented for the design of elastic surface wave filters operating at resonance/anti-resonance frequencies above 1 GHz.

Today, there is interest in forming elastic surface wave filters formed on POI substrates and operating at resonance/anti-resonance frequencies below 1 GHz. However, in order to keep the temperature coefficient of frequency of a surface elastic mode propagating on a POI substrate to reasonable values (e.g., below 10 ppm·K⁻¹), it may be necessary to adapt the thicknesses of the piezoelectric material layer and/or the dielectric material layer. In particular, it may be necessary to reduce the thickness of the dielectric material layer and/or increase the thickness of the piezoelectric material layer.

In this respect, the SmartCut™ process offers the versatility needed to adapt the thicknesses of these layers.

However, a thin layer of dielectric material and, in particular, one with a thickness of less than 300 nm or even less than 200 nm, is no longer an effective barrier to the diffusion of certain species likely to form the layer of piezoelectric material. For example, a layer of dielectric material less than 300 nm thick will diffuse lithium from a layer of piezoelectric material comprising LaTiO₃. In particular, lithium diffusing into the layer of dielectric material (e.g., SiO₂) causes radio-frequency losses.

It is also undesirable to consider a layer of piezoelectric material with a thickness that is too great and, in particular, greater than 500 nm. In fact, when using the SmartCut™ process to form the POI substrate, these thicknesses require relatively high implantation energies to be considered in the solid substrate of piezoelectric material (the donor substrate), which consequently generate damage that is often prohibitive for the formation of elastic surface wave filters.

### BRIEF SUMMARY

One object of the present disclosure is, therefore, to propose a method for manufacturing an elastic surface wave device, operating at frequencies below 1 GHz, implementing a SmartCut™ process and for which the diffusion of species during the execution of the process remains limited.

The purpose of the present disclosure is achieved by a method for manufacturing an elastic wave device configured to operate at a frequency lower than 1 GHz, and formed on a POI substrate, the formation of the POI substrate comprising the following steps:
a) a step of implanting species in a donor substrate, comprising LaTiO₃, the implanting of species being intended to form a layer, called the embrittlement zone, in the volume of the donor substrate, and delimiting, with a face, called the main face, of the donor substrate, a useful layer;
b) a step of transferring the useful layer onto a front face of a support substrate, the transfer step comprising in order an assembly of the useful layer with a face, called front face, of the support substrate, and a heat treatment intended to initiate a fracture wave along the embrittlement in order to transfer the useful layer onto the front face;
the method further comprising the formation of an intermediate stack, positioned between the front face and the useful layer, the intermediate stack comprising, from the front face, a first layer, a second layer and a third layer, the first layer comprising silicon dioxide, the second layer comprising silicon nitride, alumina or aluminum nitride, and the third layer comprising silicon dioxide or amorphous silicon.

According to one embodiment, the POI substrate formation also comprises a layer, called a trapping layer, positioned between the intermediate stack and the front face, the trapping layer being adapted to limit the mean free path of electric carriers at the interface formed between the intermediate stack and the trapping layer with respect to the mean free path of electric carriers at an interface formed between the intermediate stack and the support substrate.

According to one embodiment, the trapping layer comprises a defect density greater than a predetermined defect density, the predetermined defect density being a defect density for which the resistivity of the trapping layer is greater than or equal to 10 Kilo-ohm for temperatures between −20° C. and 120° C.

According to an embodiment, the trapping layer comprises at least one of the following materials: amorphous silicon, polycrystalline silicon.

According to an embodiment, the formation of the stack comprises forming the third layer on the main face before carrying out implantation step a).

According to an embodiment, forming the stack comprises forming the first layer and the second layer on the front face so that assembly, when step b) is carried out, comprises bringing the second layer and the third layer into contact.

According to an embodiment, the third layer is between 10 nm and 100 nm thick.

According to an embodiment, the method comprises a preliminary step, carried out prior to step a), during which the donor substrate is subjected to a vapor-phase oxygen treatment so as to limit, or even reduce, the effects of pyroelectricity likely to appear in the donor substrate, and consequently in the useful layer, when it is subjected to a rise in temperature.

According to an embodiment, the donor substrate comprises iron-doped lithium tantalate, the iron doping being between 0.001% and 0.05%, advantageously between 0.002% and 0.01%, by weight.

According to an embodiment, the first layer has a thickness of between 100 nm and 1000 nm, advantageously between 300 nm and 800 nm, and the second layer has a thickness of between 20 nm and 300 nm.

According to an embodiment, the method comprises forming at least one electroacoustic transducer on and/or in the useful layer.

According to an embodiment, the support substrate comprises at least one of the elements chosen from: a silicon substrate with orientation 110, a quartz substrate with orientation (YXt)/θ/90° with θ between −20° and 60°, advantageously between −10° and 30°, for example, equal to 5°.

According to an embodiment, the LiTaO₃ material has a (YX)/θ orientation with θ between 10° and 52°, advantageously between 15° and 30°.

### BRIEF DESCRIPTION OF THE DRAWINGS

Other features and advantages of the disclosure will emerge from the following detailed description of embodiments of the disclosure with reference to the accompanying figures.

FIG. 1 is a schematic representation of an elastic surface wave resonator according to a cross-sectional plane perpendicular to a main face of the POI substrate support conforming to the principles of the present disclosure.

FIG. 2 is a graphical representation of the evolution of the TCF₁ coefficient (vertical axis, in ppm/K), of the fundamental elastic mode of surface shear propagating under a periodic electrode array of a POI substrate, as a function of frequency (horizontal axis, in MHz), the so-called standard POI substrate that comprises in order, from the front, a 600 nm-thick layer of lithium tantalate with a (YX1)/42° cut according to the IEEE Std-176 standard on piezoelectricity, a 500 nm-thick layer of silicon dioxide, a 1 μm-thick layer of polysilicon, and a type (100) silicon substrate.

FIG. 3 is a graphical representation of the evolution of the TCF₁ coefficient (vertical axis, in ppm/K), of an elastic surface mode propagating under a periodic electrode array of a POI substrate, as a function of frequency (horizontal axis, in MHz), in particular, curve C and curve D represent the TCF₁ coefficient associated with a POI substrate that comprises a support substrate made of silicon, respectively, of the (110) type or of the (XYt)/45° or (YXt)/45° type according to the IEEE Std-176 standard.

FIG. 4 shows the variation of the TCF₁ (vertical axis in ppm/K) of the fundamental elastic mode of surface shear propagating on a POI substrate and as a function of the cutting angle θ (horizontal axis, in ° of angle) of the LiTaO₃ layer, the POI substrate under consideration comprising a support substrate made of silicon, and a 350-nm thick SiO₂ layer positioned between the support substrate and the LiTaO₃ layer.

FIG. 5 shows the variation of the electromechanical coupling (vertical axis, in %) of the fundamental elastic mode of surface shear propagating on a POI substrate described in relation to FIG. 4 and as a function of the cutting angle θ (horizontal axis, in °) of the LiTaO₃ layer.

FIG. 6 is a schematic representation of an elastic surface wave resonator according to a cross-sectional plane perpendicular to a main face of the POI substrate support conforming to the principles of the present disclosure.

FIG. 7 shows graphically (in 3D representation) the phase velocity of waves likely to propagate in the LiTaO₃ layer 5 of an elastic surface wave device formed from the POI substrate described above. The phase velocity, denoted vφ (vertical axis, in m/s), is plotted as a function of the device's operating frequency (A axis in MHz) and the thickness of the SiO₂ layer 6 (B axis in nm).

FIG. 8 graphically represents (according to a 3D representation) the electromechanical coupling factor of the fundamental elastic mode of surface shear propagating on a POI substrate described above, the electromechanical coupling factor, denoted kₛ² (vertical axis, in %), is represented as a function of the operating frequency of an infinite periodic transducer formed on the POI substrate (A axis in MHz) and the thickness of the SiO₂ layer 6 (B axis in nm).

FIG. 9 graphically represents (in a 3D representation) the TCF₁ coefficient of the fundamental elastic mode of surface shear propagating in a POI substrate described above. The TCF₁ coefficient, denoted TCF₁ (vertical axis, in ppm/K), is represented as a function of the transducer operating frequency (A axis in MHz) and the thickness of the SiO₂ layer 6 (B axis in nm).

FIG. 10 shows graphically (in a 3D representation) the electromechanical coupling factor of the fundamental elastic mode of surface shear propagating in the POI substrate described above and whose LiTaO₃ layer 5 thickness is equal to 700 nm. The electromechanical coupling factor, denoted kₛ² (vertical axis, in %), is represented as a function of the operating frequency of the transducer formed on the POI substrate (A axis in MHz) and of the SiO₂ layer 6 thickness (B axis in nm).

FIG. 11 graphically represents (in 3D representation) the TCF₁ coefficient of the fundamental elastic mode of surface shear propagating on a POI substrate described above and whose LiTaO₃ layer thickness is equal to 700 nm. The TCF₁ coefficient, denoted TCF₁ (vertical axis, in ppm/K), is represented as a function of the transducer operating frequency (A axis in MHz) and the SiO₂ layer thickness (B axis in nm).

FIG. 12 shows graphically (in a 3D representation) the electromechanical coupling factor of the fundamental elastic mode of surface shear propagating on the POI substrate described above and whose LiTaO₃ layer thickness is equal to 800 nm. The electromechanical coupling factor, denoted Kₛ² (vertical axis, in %), is represented as a function of the operating frequency of the transducer formed on the POI substrate (A axis in MHz) and the thickness of the SiO₂ layer (B axis in nm).

FIG. 13 graphically represents (in a 3D representation) the TCF₁ coefficient of the fundamental elastic mode of surface shear propagating on a POI substrate described above and whose LiTaO₃ layer thickness is equal to 700 nm. The TCF₁ coefficient, denoted TCF₁ (vertical axis, in ppm/K), is represented as a function of the transducer operating frequency (A axis in MHz) and the thickness of the SiO₂ layer 6 (B axis in nm).

FIG. 14 is a graphical representation of the evolution of the phase velocity of the fundamental shear mode (vertical axis, in m/s) as a function of frequency (horizontal axis in MHz) and propagating in a POI substrate that comprises a 600 nm LiTaO₃ (YX1) 42° layer, a 100 nm additional layer, a 400 nm dielectric layer, and a Silicon support substrate, the additional layer being able to comprise diamond carbon, GaN, ZnO, LiNbO₃.

FIG. 15 is a graphical representation of the evolution of the phase velocity of the fundamental shear mode (vertical axis, in m/s) as a function of frequency (horizontal axis in MHz), and propagating in a POI substrate that comprises a 600 nm LiTaO₃ (YX1) 42° layer, a 100 nm additional layer, a 400 nm dielectric layer, and a Silicon support substrate, the additional layer being able to comprise: SiN, poly Si, AlN, Al₂O₃.

FIG. 16 is a schematic representation of an elastic surface wave device according to a cross-sectional plane perpendicular to a front face of the support substrate conforming to the principles of the present disclosure.

FIG. 17 is a schematic representation of step a) of the method according to the present disclosure.

FIG. 18 is a schematic representation of the formation of the first and second layers on the support substrate.

FIG. 19 is a schematic representation of the assembly of the second layer with the third layer.

FIG. 20 is a schematic representation of the fracture along the embrittlement zone.

### DETAILED DESCRIPTION

For the sake of simplifying the following description, the same references are used for elements that are identical or perform the same function in different disclosed embodiments of the disclosure and in the prior art.

The present disclosure relates to an elastic surface wave device formed from a POI substrate. In this respect, document FR3127660 describes an elastic surface wave device and its operating principle.

According to the present disclosure, the elastic surface wave device can be a filter, a resonator or a sensor. It is understood, however, that the present disclosure is not limited to these aspects, and the person skilled in the art will be able to adapt its principles to any type of elastic surface wave device formed from a POI substrate.

In particular, the present disclosure relates to an elastic surface wave device produced on a POI substrate. In particular, the POI substrate comprises, from a front face to a rear face, a layer of piezoelectric material, a layer of dielectric material and a support substrate.

In this respect, the support substrate comprises at least one of the elements selected from: a silicon substrate with (110) type orientation, a quartz substrate with (YXt)/θ/90° orientation with θ between −20° and 60°, advantageously between −10° and 30°, for example, equal to 5°.

In addition, the device according to the present disclosure comprises, formed on and/or in the layer of piezoelectric material, at least one electroacoustic transducer. For example, and without limiting the scope of the present disclosure, the elastic surface wave device comprises at least one input electroacoustic transducer and at least one output electroacoustic transducer formed on or in the layer of piezoelectric material. The at least one electroacoustic transducer according to the present disclosure can be equipped with Bragg mirrors with electrodes. The electrodes can be arranged periodically and, in particular, have a repetition period close to that of electrodes of the at least one transducer, located on either side of the transducer. The structure can include at least one free surface gap within it. The resonator thus formed is used as the impedance element of a filter combining one or more identical cells incorporating at least one resonator as described above.

It is understood that the orientation of a substrate or layer must be associated with its crystalline orientation, defined according to IEEE standard 1949 Std-176.

It is also understood that an angular deviation from a crystalline orientation may be allowed. In particular, whatever the crystalline orientation considered, it will be generally accepted that the latter is specified to within 10°, advantageously to within 5°, of the orientation.

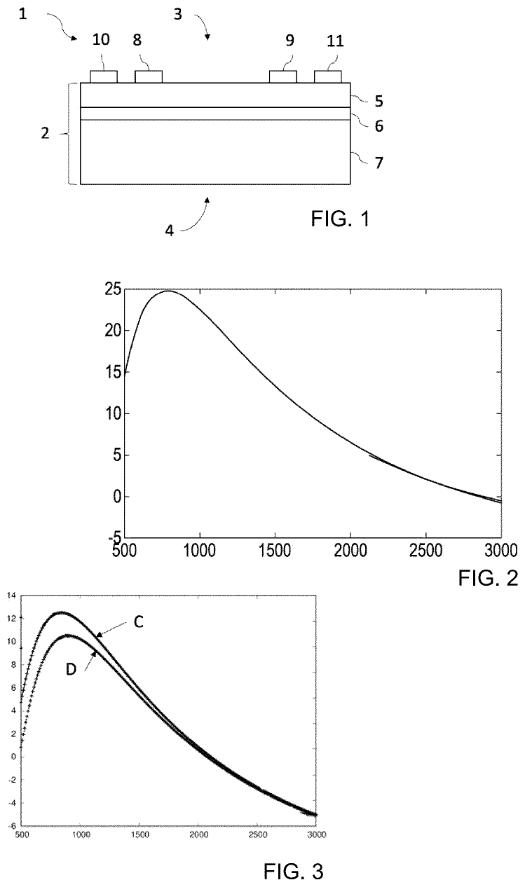

FIG. 1 is a schematic illustration of an elastic surface wave device 1 (in particular, in this FIG. 1, the device is a resonator).

In particular, the elastic surface wave device 1 comprises a POI substrate 2.

In this respect, the POI substrate 2 comprises, from a front face 3 to a rear face 4, a layer of piezoelectric material 5, a first layer 6 of dielectric material and a support substrate 7.

By way of example, the elastic surface wave device 1 is a bandpass filter with a center frequency f₀ and a bandwidth Δf that can be expressed as a fraction of this center frequency, typically between 0.1% and 10% with a POI substrate provided with a piezoelectric layer 5 made of lithium tantalate LiTaO₃. Consideration of a LiNbO₃-based piezoelectric layer 5 makes it possible to push the upper limit of this fraction to 15% and more by choosing the crystalline orientation of the layer so as to maximize the electromechanical coupling of the mode thus exploited.

According to one embodiment, the elastic surface wave device 1 comprises at least one electroacoustic transducer, for example, and as shown in FIG. 1, at least one input electroacoustic transducer 8 and at least one output electroacoustic transducer 9.

According to another embodiment, the elastic surface wave filter is composed of at least one cell provided with at least one elastic surface wave resonator forming a quadrupole with an input port and an output port. These are acoustically coupled filters known to the person skilled in the art as LCRF (Longitudinally Coupled Resonator Filter), DMS (Double Mode SAW) filters or SCAW (Surface Cavity Acoustic Wave) filters. When several cells with a single transducer or several transducers connected together to form a dipole are cascaded by electrical connection only, the resulting filter is generally referred to as an impedance element filter. In operation, the electromagnetic signal to be filtered is applied to the filter input port and the filtered electromagnetic signal is taken from the filter output port. However, it should be noted that the “input” and “output” designation is totally arbitrary and that the device, and particularly the elastic surface wave filter 1, can be exploited by applying/presampling an electromagnetic signal on either of the two ports.

In very general terms, the input electroacoustic transducer 8 and the output electroacoustic transducer 9, as well as the resonators used as impedance elements in filters with cells arranged in cascades, conform to those known in the state of the art, some features of which are recalled below.

Each transducer 8 and 9 comprises two interdigitated comb electrodes. Such transducers 8 and 9 are each formed by an array of metal fingers that are alternately connected to two buses between which an electrical potential difference is applied/sensed. With this device it is possible to directly generate/detect an elastic surface wave in the piezoelectric upper layer 5. Input electroacoustic transducer 8 and output electroacoustic transducer 9 are generally configured to be identical. However, the disclosure is not limited to this aspect, and the person skilled in the art will be able to consider two different transducers.

These filters are generally referred to as transversal filters. Indeed, their transfer function can advantageously be modulated by the interpenetration of comb-shaped electrodes along the direction of wave propagation. For this type of component, transducers are likely to operate outside the Bragg condition. These filters are said to have a finite impulse response. The person skilled in the art can also use transducers operating under the Bragg condition, to which mirrors are advantageously added at each end of the filter to reflect the energy in phase back into the structure in question, thus giving rise to filters with infinite impulse response. The impedance element filters mentioned above also correspond to infinite impulse response filters in that they are made up of resonant elements.

The metal of the electrodes is typically based on aluminum, for example, pure aluminum or an aluminum alloy such as aluminum doped with Cu, Si or Ti. It is nevertheless possible to use another material, for example, to establish a higher reflection coefficient for a lower relative electrode thickness, than the one needed with aluminum in order to achieve similar characteristics. In this respect, preferred electrode materials are copper (Cu), molybdenum (Mo), nickel (Ni), platinum (Pt) or gold (Au) with an adhesion layer such as titanium (Ti) or tantalum (Ta) or chromium (Cr), zirconium (Zr), palladium (Pd), iridium (Ir), tungsten (W), etc. The electrodes can also be made of two of the above materials to optimize transducer operation via their acoustic reflection functions of electromechanical coupling and losses, particularly ohmic losses.

The period p of the electrodes is generally chosen such that p=λ/2, λ being the wavelength of the elastic wave propagating in the layer of piezoelectric material 5 at the transducer synchronism frequency fₛ given by fₛ=V_{φ}/λ, V_{φ} representing the phase velocity of the mode operated. The transducer then operates under the Bragg condition already mentioned above. Other configurations are possible, and more generally the period p can be written as p=λ/(nb_elec), with nb_elec being the number of fingers (electrodes) per wavelength. These parameters are linked by the relationship λ=V/fₛ, wherein V represents the phase velocity of the elastic wave under the transducer. The speed of the elastic wave on the free surface or under an electroacoustic transducer depends, in particular, on the nature of the material wherein the wave propagates. The latter is generally known or accessible to the person skilled in the art by specifically using the elastic, piezoelectric and dielectric constants and density tabulated in the literature in suitable models.

In the case of the bandpass filter, in particular, with a given frequency and bandwidth, it may be considered to use transducers whose synchronization frequencies are chosen to meet the above-mentioned requirements. The methods for implementing this choice or these choices are known to the person skilled in the art and are, therefore, not described.

The metallization width of the electrodes, denoted a, is generally chosen so that the a/p ratio is of the order of 0.5. This aspect does not limit the scope of the present disclosure, and the person skilled in the art will be able to consider other ratios that may prove more advantageous for a given mode/material pairing. The number of pairs of fingers of each transducer is usually but not exclusively chosen in the order of 20 or 100. Generally speaking, increasing the number of finger pairs increases the rejection of out-of-band frequencies and reduces the spectral range of the transducer's admittance or impedance response around its synchronous frequency.

The elastic surface wave device 1 may also include two external mirrors 10 and 11 arranged on either side of the pair of input 8 and output 9 electroacoustic transducers. As is well known, these mirrors 10, 11 make it possible to confine as much of the elastic energy as possible between the two input 8 and output 9 electroacoustic transducers. As such, they are designed to have a very high reflection coefficient, as close as possible to 1 (total reflection of the incident energy), by choosing the thickness of the electrodes of the mirrors and the number of these electrodes, typically a few tens per mirror in the case of a POI substrate for a shear wave. It should however be noted that these two external mirrors are in no way essential to the disclosure, and that a device according to the disclosure and entirely functional can be devoid of them.

The aim of the present disclosure is to propose a device, for example, a filter (without, however, limiting the disclosure to this aspect alone), with elastic surface waves 1 for which the temperature sensitivity remains limited for frequencies below 1 GHz.

In this respect, the temperature behavior of an elastic surface wave filter is generally correctly represented by the following relationship:

$$Δ f / f = {TCF}_{1} \times ( T - {T}_{0} ) + {TCF}_{2} \times {( T - {T}_{0} )}^{2}$$

Temperature sensitivity requirements dictate that the TCF₁ coefficient must be kept below a threshold value over the operating frequency range of the elastic surface wave device. More particularly, it is advantageous to maintain the TCF₁ coefficient at a value below 20 ppm/K, advantageously below 15 ppm/K, even more advantageously below 10 ppm/K.

It was found that POI substrates known in the art exhibit relatively high temperature sensitivity when used to manufacture elastic surface wave devices operating at frequencies below 1 GHz and, more particularly, between 400 MHz and 1 GHz.

It is understood that all the graphical representations described in the following statement of the present disclosure are the result of numerical simulations on the basis of models (implementing an analysis based on Green's functions of the substrates and numerical methods such as finite elements and boundary elements) taking into account the characteristics of the transducers studied. Details of these simulations are not presented in the following description. However, the person skilled in the art will find in document [3], cited at the end of the description, the theoretical elements enabling them to be reproduced.

By way of example, FIG. 2 (curve A) shows the variation in the TCF₁ coefficient of the fundamental elastic mode of surface shear propagating on a substrate POI known from the state of the art. In particular, this substrate comprises, from a front face to a rear face, the following layers:
a layer of LiTaO₃ with an (XY1)/42° cross-section, 600 nm thick
an SiO₂ layer with a thickness of 500 nm
a silicon substrate of type 100 and a thickness equal to 650 μm (the silicon substrate is assumed to be semi-infinite within the calculation of the variation of the TCF₁ coefficient).

In this FIG. 2, the TCF₁ coefficient of the fundamental elastic mode of surface shearing propagating on the POI substrate known from the state of the art remains below 15 ppm/K for operating frequencies above 1.3 GHz, but can reach values above 20 ppm/K, or even 25 ppm/K, when the frequency is below 1 GHz.

To overcome this problem, the effect of the crystalline orientation of the silicon substrate 7 was studied.

In particular, a reduction in the TCF₁ coefficient was clearly observed when the 100-type silicon substrate was replaced by a 110-type silicon substrate. Consideration of a silicon substrate 110 induces a decrease and, more particularly, a 1% decrease, in the electromechanical coupling factor of the mode under consideration.

Consideration of a support substrate made of silicon 110 reduces the TCF₁ coefficient for frequencies below 1 GHz and, in particular, between 400 MHz and 1 GHz.

In particular, according to the present disclosure, it is also possible to consider a support substrate made of silicon of type (110) (or (XYw)/45° is according to the IEEE Std-176 standard) or of type IEEE Std-176 (XYt)/45°.

In this respect, FIG. 3 graphically shows the evolution of the TCF₁ coefficient as a function of the frequency of fundamental elastic modes of surface shear, each guided on a different POI substrate. Each POI substrate under consideration comprises a layer of piezoelectric material made of LiTaO₃ and having a thickness equal to 700 nm, and a layer of dielectric material made of SiO₂ and having a thickness equal to 350 nm. Furthermore, curve C is obtained for a POI substrate comprising a 110-type silicon support substrate, while curve D is obtained for a POI substrate comprising an IEEE Std-176-type silicon support substrate (XYt)/45° or (YXt)/45°.

In both cases, the TCF₁ coefficient remains below 13 ppm/K, while the electromechanical coupling of the elastic surface mode under consideration is little affected compared to that observed when the fundamental surface shear elastic mode is guided by a POI substrate known from the state of the art.

It was noted that it is also possible to consider a support substrate made of quartz with an orientation (YX/t)/θ/90° with θ between −20° and 60°, advantageously between −10° and 30°, for example, equal to 5°.

Alternatively or additionally, and in order to reduce the TCF₁ coefficient, it is possible to adapt the stack formed on the support substrate 7. In particular, the first layer 6 of dielectric material comprises silicon dioxide and has a thickness greater than 300 nm, advantageously between 300 nm and 600 nm, even more advantageously between 300 nm and 400 nm.

Equivalently, a layer can be considered of piezoelectric material 5 made of LaTiO₃ or LiNbO₃ with a thickness of between 300 nm and 1000 nm, advantageously less than 800 nm, even more advantageously less than 700 nm.

The effect of the crystalline orientation of the piezoelectric material layer on the amplitude of the TCF₁ coefficient was also studied. In order to show the effect of the crystalline orientation of the piezoelectric material layer, it is proposed to consider a surface mode guided by a POI substrate that comprises, from its front face to its rear face, a LiTaO₃ layer that has a thickness of 700 nm and a crystalline orientation (YZ1)/θ (with θ between 0° and 30°), a SiO₂ layer that has a thickness of 350 nm and a support substrate made of silicon.

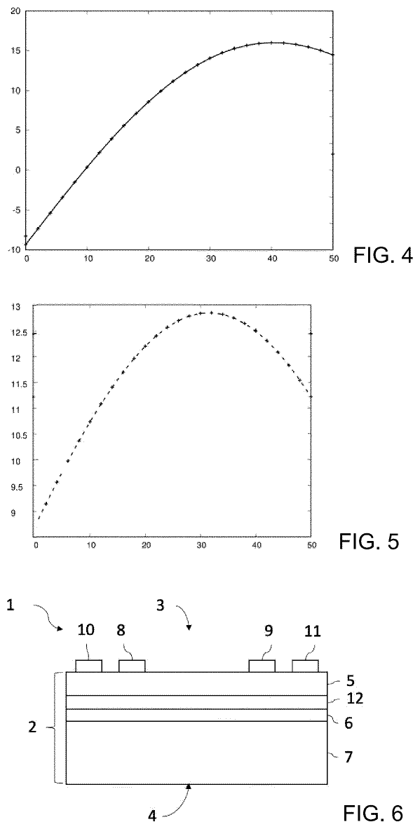

More specifically, FIGS. 4 and 5 show the variation, respectively, of the TCF₁ coefficient and the electromechanical coupling associated with the fundamental elastic mode of surface shear guided by a POI substrate described above and as a function of the angle θ of the LiTaO₃ layer. Thus, for values of 0 between 10° and 35°, advantageously between 15° and 30°, the TCF₁ coefficient remains below 15 ppm/K and the electromechanical coefficient is greater than 10%.

According to a complementary or alternative aspect to the above, the POI substrate according to the present disclosure may further comprise a second layer 12 positioned between the layer of piezoelectric material 5 and the first layer 6 of dielectric material (FIG. 6). The second layer 12 is advantageously associated with a temperature coefficient of frequency of opposite sign to that with which the dielectric material layer 5 is associated. The latter compensates for the effect of the dielectric layer 6 on the TCF₁ coefficient.

It is understood, according to the present disclosure, that a temperature coefficient of frequency associated with a layer of a given material, corresponds to the temperature coefficient of frequency of a surface elastic mode propagating on the layer. It is also understood that, in the present case, two temperature coefficients of frequency for frequencies below 1 GHz were compared.

The additional layer may comprise a dielectric material and/or a semiconductor or piezoelectric material.

According to the present disclosure, when the dielectric layer 6, for example, made of SiO₂, is associated with a positive temperature coefficient of frequency, that with which the second layer 12, for example, made of SiN, Al₂O₃ or AlN, is associated, is negative.

Furthermore, in order not to disturb the properties of the fundamental acoustic shear modes guided by the stack of material forming the POI substrate, the additional layer may have, for frequencies below 1 GHz, an acoustic impedance greater than or equal to that of the first layer 6 of dielectric material.

Consideration of the second layer 12 also makes it possible to reduce the TCF₁ coefficient of a fundamental elastic mode of shear guided on POI. When the layer comprises silicon nitride (SiN), this reduction can reach 5 ppm/K or even more, depending on the thickness of the layer.

The addition of a step to produce an additional TCF layer of opposite sign to that of the dielectric material layer enables the thicknesses of the piezoelectric layer/dielectric layer to be reduced/increased respectively to achieve a given TCF, and thus to transfer the piezoelectric layer by a SmartCut™ process without damaging it and without inducing lithium diffusion in the support substrate. The risk of lithium diffusion comes into play during annealing, either to strengthen the bonding interface or to exodiffuse implanted hydrogen (which can invert p-domains).

It is understood without needing to be said that the silicon nitride considered in the present disclosure is not necessarily stoichiometric.

It was also noted that positioning the second layer 12 under the first layer 6 of dielectric material has no appreciable effect on the TCF₁ coefficient of an elastic surface mode propagating in the POI substrate.

Advantageously, the second layer 12 has a thickness of between 20 and 300 nm.

The use of the second layer 12 makes it possible to consider a dielectric layer 6 of greater thickness.

In addition, a second layer 12 made of SiN and a first layer 6 of dielectric material made of SiO₂ can be formed in the same step of a method, in particular, in a Pressure Enhanced Chemical Vapor Deposition (PECVD) frame.

As an illustration of the use of the second layer 12, its effect on the TCF₁ coefficient of the fundamental elastic mode of surface shear guided on the POI substrate was estimated. This simulation uses Green's function analysis to represent the dispersive behavior of modes on laminated substrates.

The POI substrate considered in this analysis comprises, from its front face to its rear face:
a layer 5 of LiTaO₃ oriented along the (YX1)/42° section of this crystal and 600 nm thick;
a layer 12 of SiN with a thickness of 100 nm;
a layer 6 of SiO₂ with a thickness that can assume one of the values between 300 nm and 600 nm; and
a support substrate 7 made of silicon.

The POI substrate can also include a polycrystalline silicon trapping layer with a thickness of the order of 1 μm and more generally between 400 nm and 2 μm.

The phase velocity of the waves likely to propagate in LiTaO₃ layer 5, the electromechanical coupling factor and the TCF₁ coefficient of the fundamental elastic mode of surface shear guided on the POI substrate described above was able to be evaluated.

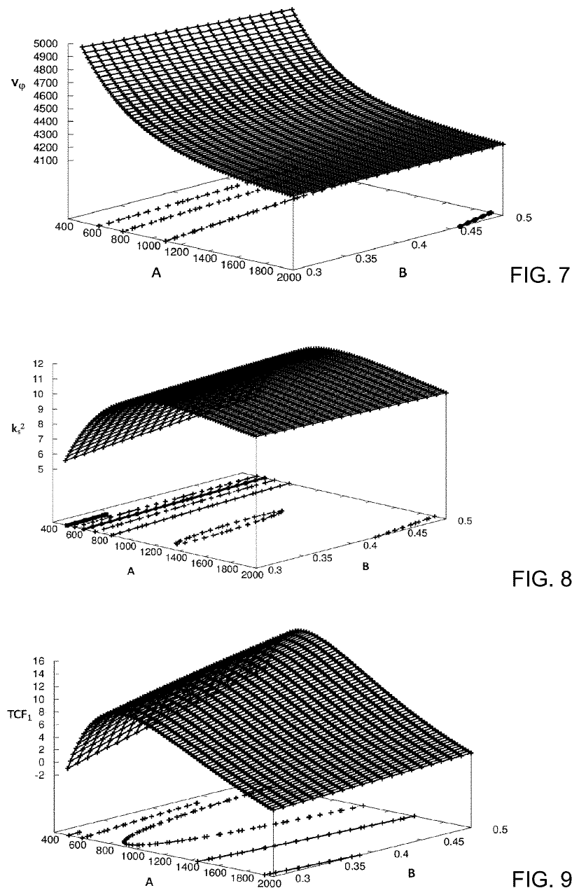

The results of these evaluations are shown in FIGS. 7 through 9.

In particular, FIG. 7 shows graphically (in 3D representation) the phase velocity of waves likely to propagate in LiTaO₃ layer 5 in the fundamental elastic mode of surface shear guided on the POI substrate described above. The phase velocity of this mode, denoted v_{φ} (vertical axis, in m/s), is plotted as a function of the filter operating frequency (A axis in MHz) and SiO₂ layer 6 thickness (B axis in nm).

FIG. 8 shows a graphical representation (in 3D) of the electromechanical coupling factor of the fundamental elastic mode of surface shear guided on the POI substrate described above. The electromechanical coupling factor, denoted kₛ² (vertical axis, in %), is plotted as a function of mode operating frequency (A axis in MHz) and SiO₂ layer 6 thickness (B axis in nm).

FIG. 9 shows a 3D graphic representation of the TCF₁ coefficient of the fundamental elastic mode of surface shear guided on the POI substrate described above. The TCF₁ coefficient (vertical axis, in ppm/K) is plotted as a function of mode operating frequency (A axis in MHz) and SiO₂ layer 6 thickness (B axis in nm).

According to FIG. 9, the TCF₁ of the surface elastic mode under consideration is less than 10 ppm/K for frequencies between 600 MHz and 2 GHz and for SiO₂ thicknesses of 350 nm or less. This relatively low value of the TCF₁ coefficient, compared with the methods used to manufacture filters known to the state of the art, is attributable to the use of the SiN layer 12. However, as shown in FIG. 7 and FIG. 8, the use of the second layer 12 induces an increase in phase velocity and a reduction in the electromechanical coupling factor of the order of 1% compared with a guided surface shear elastic wave known from the state of the art, that is, without the SiN layer.

All the elements described in the present disclosure lead to an adjustment of the TCF₁ coefficient. Indeed, the technical objective of the present disclosure is to limit or control the effect of temperature on the operation of an elastic surface wave device formed from a POI substrate.

An adjustment is shown by way of example by considering an elastic surface wave device formed from the POI substrate, which comprises from its front face to its rear face:
a layer 5 of LiTaO₃ oriented at an angle (YX1)/42°;
a layer 12 of SiN with a thickness of 100 nm;
a layer 6 of SiO₂ with a thickness that can assume one of the values between 300 nm and 600 nm;
a trapping layer comprises polycrystalline silicon, having a thickness of the order of 1 μm; and
a support substrate 7 made of silicon.

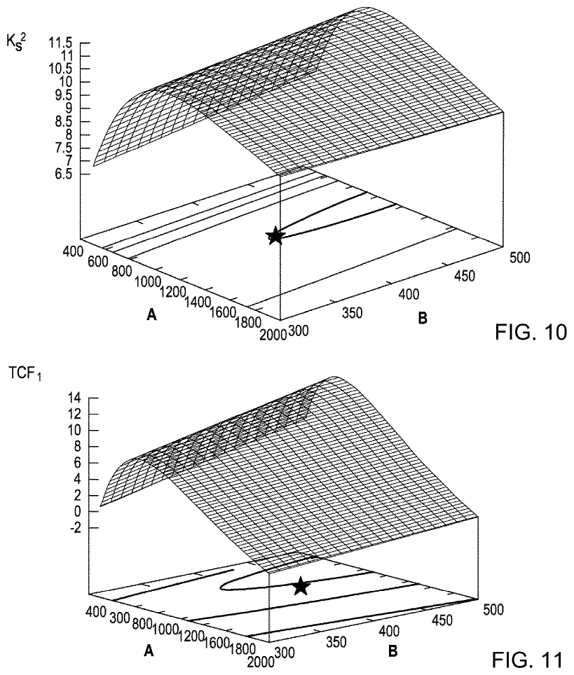

The results of these evaluations are shown in FIGS. 10 through 13.

FIG. 10 shows a 3D graphic representation of the electromechanical coupling factor for the fundamental elastic mode of surface shear guided on the POI substrate described above, with LiTaO₃ layer 5 thickness equal to 700 nm. The electromechanical coupling factor, denoted kₛ² (vertical axis, in %), is plotted as a function of mode operating frequency (A axis in MHz) and SiO₂ layer 6 thickness (B axis in nm).

FIG. 11 shows a 3D graphic representation of the TCF₁ coefficient for the fundamental elastic mode of surface shear guided on the POI substrate described above, with LiTaO₃ layer 5 thickness equal to 700 nm. The TCF₁ coefficient, denoted TCF₁ (vertical axis, in ppm/K), is plotted as a function of mode operating frequency (A axis in MHz) and SiO₂ layer 6 thickness (B axis in nm).

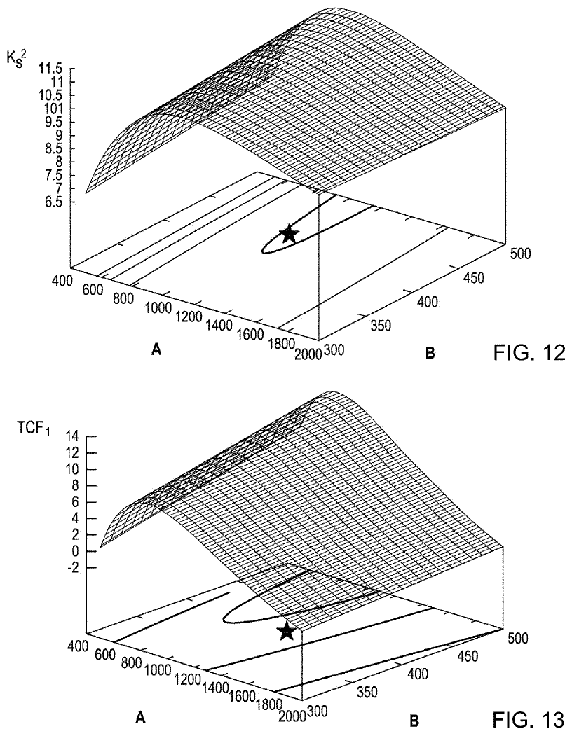

FIG. 12 shows a 3D graphic representation of the electromechanical coupling factor for the fundamental elastic mode of surface shear guided on the POI substrate described above, with LiTaO₃ layer 5 thickness equal to 800 nm. The electromechanical coupling factor, denoted kₛ² (vertical axis, in %), is plotted as a function of mode operating frequency (A axis in MHz) and SiO₂ layer 6 thickness (B axis in nm).

FIG. 13 shows a 3D graphic representation of the TCF₁ coefficient for the fundamental elastic mode of surface shear guided on the POI substrate described above, with LiTaO₃ layer 5 thickness equal to 800 nm (the star corresponds to an operating point for which kₛ² is maximum, while the TCF₁ coefficient is minimum). The TCF₁ coefficient, denoted TCF₁ (vertical axis, in ppm/K), is plotted as a function of mode operating frequency (A axis in MHz) and SiO₂ layer 6 thickness (B axis in nm).

With a SiO₂ layer 6 less than 400 nm thick and a LiTaO₃ layer 700 nm thick, the second SiN layer 12 provides an electromechanical mode coupling factor of over 10% (FIG. 10) for frequencies between 800 MHz and 1600 MHz, and a TCF₁ᵣ coefficient close to 10 ppm/K (FIG. 11).

Equivalently, the same second SiN layer 12, for a SiO₂ layer 6 with a thickness of less than 400 nm and a LiTaO₃ layer with a thickness of 800 nm, achieves an electromechanical mode coupling factor greater than 11% (FIG. 12) for frequencies between 800 MHz and 1600 MHz, and a TCF₁ᵣ coefficient close to less than 10 ppm/K (FIG. 13).

The entire description is limited to the parameters relating to the fundamental shear mode according to its operating frequency, and more specifically to the control of the TCF₁ parameter characterizing the surface elastic mode under consideration. However, the person skilled in the art will understand that an elastic surface wave device based on the exploitation of the mode of interest also has a resonance frequency and an antiresonance frequency, itself characterized by its own TCF₁ coefficient. A very low or even zero TCF₁ coefficient, characterizing resonance, can have a negative impact on the TCF₁ coefficient characterizing the antiresonance of the device in question, particularly in the case of single-rotation cuts of lithium niobate and tantalate, which are known to have mutually different TCFs for resonance and antiresonance for the same mode and particularly for shear modes.

The present disclosure, therefore, also proposes optimizing the parameters characterizing the POI substrate in order to better appreciate the TCF₁ coefficients relating, respectively, to the resonance and anti-resonance of a device formed on the substrate. More particularly, the present disclosure proposes adjusting the TCF₁ coefficient relating to resonance (hereinafter TCF₁r) and the TCF₁ coefficient relating to antiresonance (hereinafter TFC_{1AR}). In particular, the present disclosure proposes adjusting the TCF₁ᵣ coefficient to values below 15 ppm/K and the TFC_{1AR} coefficient to values between −4 ppm/K and 0 ppm/K. Equivalently, the present disclosure proposes adjusting the TCF_{1R} coefficient to lower values between 5 ppm/K and 10 ppm/K and the TFC_{1AR} term to values between −10 ppm/K and −5 ppm/K.

These objectives can be achieved by simulating the evolution of the various terms and coefficients described above, in order to define the material layers and their respective thicknesses.

Materials other than SiN for forming the second layer 12 were also studied.

More particularly, the second layer 12 can comprise at least one of the materials selected from: SiC, Al₂O₃, AlN, diamond carbon, GaN, LiNbO₃, ZnO.

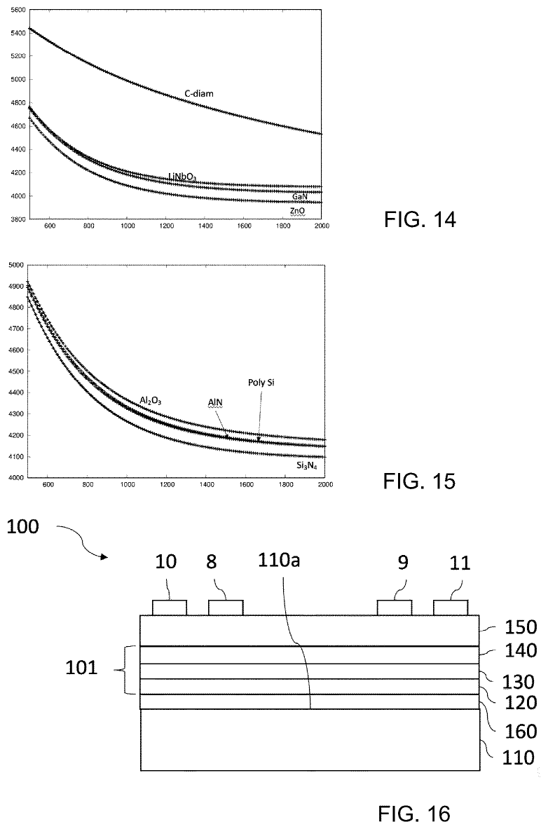

FIG. 14 is a graphical representation of the phase velocity evolution of the fundamental shear mode (vertical axis, in m/s) as a function of frequency (horizontal axis in MHz) on a POI substrate that comprises a 600 nm LiTaO₃ (YX1) 42° layer, a 100 nm additional layer, a 400 nm dielectric layer, and a Silicon support substrate, the additional layer possibly comprising diamond carbon, GaN, ZnO, LiNbO₃.

FIG. 15 is a graphical representation of the phase velocity evolution of the fundamental shear mode (vertical axis, in m/s) as a function of frequency (horizontal axis in MHz) on a POI substrate that comprises a 600 nm LiTaO₃ (YX1) 42° layer, a 100 nm additional layer, a 400 nm dielectric layer, and a Silicon support substrate, the additional layer may comprise SiN, poly-Si, AlN, Al₂O₃.

With the exception of diamond carbon, the same behavior is observed when the phase velocity of the mode tends towards the shear wave velocity in silicon at low frequencies. Decreasing the mode speed is equivalent to increasing the wavelength of the mode considered for a given frequency, and thus reduces the influence of the composite structure of the POI substrate.

From these observations and an appropriate mathematical treatment (consideration of the derivative of the phase velocity with respect to frequency), it emerges that LiNbO₃ is the most favorable material for minimizing modal sensitivity to frequency in the 800-1200 MHz range.

A second layer 12 made of diamond carbon seems advantageous for frequencies below 800 MHz.

An additional 100 nm thick LiNbO₃ layer between a SiO₂ dielectric layer 6 and a LiTaO₃ piezoelectric layer 5 reduces the TCF₁ coefficient to less than 10 ppm/K, irrespective of the piezoelectric layer's crystalline orientation.

The present disclosure as previously described covers a plurality of aspects that can be considered independently or in combination in order to optimize (reduce) the TCF₁ coefficient to values below 20 ppm/K, advantageously below 15 ppm/K, even more advantageously below 10 ppm/K, as long as the operating frequency of the device and, in particular, of the elastic surface wave filter, is below 1 GHz.

Advantageously, the POI substrate also comprises a trapping layer positioned between the dielectric material layer and the support substrate, the trapping layer being adapted to limit the mean free path of electrical carriers at the interface formed between the dielectric material layer and the trapping layer with respect to the mean free path of electrical carriers at an interface formed between the dielectric material layer and the support substrate.

In this respect, the trapping layer can comprise polycrystalline silicon and advantageously has a thickness of between 400 nm and 2000 nm.

The disclosure also relates to a method for producing an elastic surface wave device.

The method includes forming the elastic surface wave device from a POI substrate. The method advantageously includes forming the POI substrate.

Method of manufacturing an elastic wave device configured to operate at a frequency below 1 GHz, and formed on a POI substrate.

The formation of the POI substrate advantageously comprises the following steps:
a) a step of implanting species in a donor substrate, made of a piezoelectric material, the species implantation being intended to form a layer, called the embrittlement zone, in the volume of the donor substrate, and delimiting, with a face, called the main face, of the donor substrate, a useful layer;
b) a step of transferring the useful layer onto a front face of a support substrate, the transfer step comprising in order an assembly of the useful layer with a face, called front face, of the support substrate, and a heat treatment intended to initiate a fracture wave along the embrittlement zone in order to transfer the useful layer onto the front face;

The method further comprises forming an intermediate stack 101, positioned between the front face and the useful layer, and that comprises, starting from the front face, a first layer, a second layer and a third layer, the first layer and the third layer comprising silicon dioxide, and the second layer comprising silicon nitride.

Thus, FIG. 16 is an illustration of a POI substrate 100 that can be obtained by carrying out the manufacturing process according to the present disclosure. In particular, the POI substrate comprises, in order, a support substrate 110, a first layer 120, a second layer 130, a third layer 140 (the first layer 120, the second layer 130 and the third layer 140 forming an intermediate stack 101) and a useful layer 150.

In this respect, the first layer 120 may comprise SiO₂, the second layer 130 may comprise silicon nitride (SiN), and the third layer 140 may comprise SiO₂.

Advantageously, the POI substrate 100 can also include a trapping layer 160. In particular, the trapping layer 160 can comprise amorphous silicon and/or polycrystalline silicon.

The trapping layer 160 is positioned between the intermediate stack 101 and a front face 110a of the support substrate 110. In particular, the trapping layer 160 is adapted to limit the mean free path of electric carriers at the interface formed between the intermediate stack and the trapping layer with respect to the mean free path of electric carriers at an interface formed between the intermediate stack and the support substrate.

Advantageously, the support substrate comprises at least one of the elements chosen from: a silicon substrate with orientation 110, a quartz substrate with orientation (YX/t)/θ/90° with θ between −20° and 60°, advantageously between −10° and 30°, for example, equal to 5°.

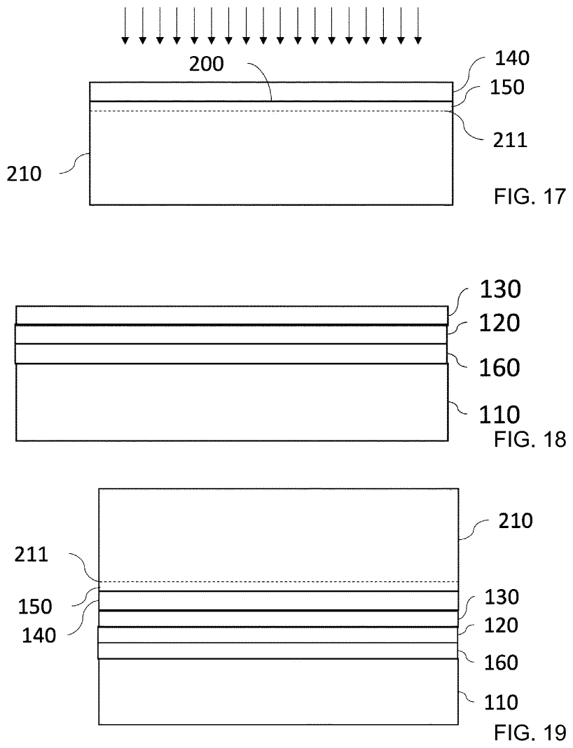

FIG. 17 shows step a). In particular, step a) comprises implanting species through a face, referred to as the main face 200, of a donor substrate 210 that comprises a piezoelectric material.

In particular, step a) is carried out in such a way as to form a layer, known as the embrittlement zone 211, in the volume of the donor substrate 210, and delimiting, with the main face 200 of the donor substrate, the useful layer 150.

It is understood, without needing to be specified, that the embrittlement zone 211 forms a layer essentially parallel to the main face 200.

It is also understood that the thickness of the useful layer 150 depends on the conditions of implantation of the species and their nature.

For example, when carrying out step a), the person skilled in the art may consider implanting hydrogen or helium ions.

Advantageously, step a) can be preceded by a preliminary step, during which the piezoelectric material is subjected to a vapor-phase oxygen treatment so as to limit, or even reduce, the pyroelectric effects likely to appear in the donor substrate, and consequently in the useful layer, when it is subjected to a rise in temperature.

The method can also comprise forming the layer of dielectric material on either the donor substrate or the carrier substrate, in particular, by PECVD.

The method can also comprise forming the additional layer, for example, on the dielectric layer if the latter is first formed on the support substrate.

Advantageously, donor substrate 210 can comprise iron-doped lithium tantalate, the iron doping being between 0.001% and 0.05%, advantageously between 0.002% and 0.01%, by weight percentage.

Advantageously, the formation of the intermediate stack 101 can include the formation of the third layer 140 on the main face prior to carrying out implantation step a). The third layer 140 can be formed by PECVD.

Advantageously, the third layer is between 10 nm and 100 nm thick.

When the third layer comprises SiO₂, the aforementioned thicknesses typically correspond to thicknesses of less than λ/20 and ideally less than λ/50, where Δ is the acoustic wavelength equal to twice the mechanical period of an interdigital transducer operating at Bragg frequency.

Equivalently, forming the intermediate stack may comprise forming the first layer 120 on a front face 110a of a support substrate 110, then forming the second layer 130 overlying the first layer 120 (FIG. 18).

Advantageously, the first layer has a thickness of between 100 nm and 1000 nm, advantageously between 300 nm and 800 nm, and the second layer has a thickness of between 20 nm and 300 nm.

The ratio of the thickness of the second layer to the thickness of the first layer will advantageously be between 1:4 and 1:3. By way of example, the thickness of the piezoelectric layer made of LaTiO₃ can be between 500 nm and 800 nm, the second layer, made of SiN, can have a thickness between 100 nm and 200 nm, and the first layer, made of SiO₂, can have a thickness between 300 and 600 nm.

The formation of the third layer 140 on the one hand, and of the first layer 120 and the second layer 130 on the other hand, is followed by a step b) of transferring the useful layer 150 onto a front face of a support substrate, the transfer step comprising, in order, an assembly of the useful layer with a face, referred to as the front face 110a, of the support substrate 110, and a heat treatment designed to initiate a fracture wave along the embrittlement zone in order to transfer the useful layer 150 onto the front face 110a.

Advantageously, assembly can comprise bringing the second layer 130 and the third layer 140 into contact (FIG. 19).

Thus, according to the present disclosure, the third layer is an adhesion layer formed at least in part on the donor substrate and, more particularly, on the main face of the donor substrate.

This latter aspect enables the hydrogen that may be present in the second layer to be exodiffused by heat treatment prior to assembly. Indeed, the second layer, comprising SiN, is obtained by gas-phase deposition of a mixture of silane with NH3 and/or N2. As a result, the second layer contains hydrogen, which must be removed to prevent it from migrating to the piezoelectric layer after step b). In this way, forming the second layer on the front face of the carrier substrate enables heat treatment to be performed only on the carrier substrate, the first layer and the second layer. The latter aspect limits the thermal history of the piezoelectric material and preserves its properties (notably limiting the risk of domain inversion). Consideration of the third layer formed, at least in part, on the main face of the donor substrate enables the latter to be regarded as a bonding layer. In other words, this aspect limits the thermal history of the piezoelectric material and limits the risk of domain inversion.

The thickness of the third SiO₂ layer is between 10 nm (full coverage) and 50 nm.

Alternatively, ADB can be bonded with a third layer of amorphous silicon a few nm thick.

The assembly is advantageously a molecular bond.

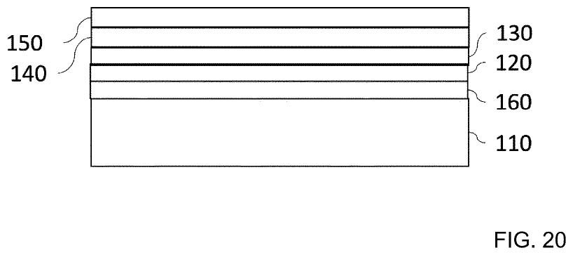

FIG. 20 shows a heat treatment designed to initiate a fracture wave along the embrittlement zone in order to transfer the useful layer 150 onto the front face to form the POI substrate shown in FIG. 16.

The method can also include forming the trapping layer 160 on the support substrate 110 prior to forming the first layer 120. In other words, the first layer 120 is formed to overlay the trapping layer.

Of course, the disclosure is not limited to the described embodiments, and variant embodiments may be envisaged without departing from the scope of the invention as defined by the claims.

### REFERENCES

[1] T. Pastureaud, et al., “High-Frequency Surface Acoustic Waves Excited on Thin-Oriented LiNbO₃ Single-Crystal Layers Transferred Onto Silicon,” IEEE Trans. on UFFC, vol. 54, no. 4, pp. 870-876, 2007;
[2] US 2014/0152146 A1;
[3] S. Ballandras, et al., “Simulations of surface acoustic wave devices built on stratified media using a mixed finite element/boundary integral formulation,” Journal of Applied Physics, Vol. 95, n 12, pp. 7731-7741, 2004.

1. A method of manufacturing an elastic wave device configured to operate at a frequency below 1 GHz, and formed on a POI substrate, the formation of the POI substrate comprising the following steps:
a) a step of implanting species in a donor substrate comprising LiTaO₃ to form a layer comprising an embrittlement zone in a volume of the donor substrate, the embrittlement zone delimiting, with a main face of the donor substrate, a useful layer; and
b) a step of transferring the useful layer onto a front face of a support substrate, the transferring comprising, in order, assembling the useful layer with a front face of the support substrate, and a heat treatment initiating a fracture wave along the embrittlement zone to transfer the useful layer onto the front face;
wherein the method further comprises forming an intermediate stack, positioned between the front face and the useful layer, the intermediate stack comprising, starting from the front face, a first layer, a second layer, the first layer comprising silicon dioxide, the second layer comprising silicon nitride, alumina or aluminum nitride.

2. The method of claim 1, wherein the intermediate stack also comprises a third layer, the second layer positioned between the first layer and the third layer, the third layer comprising silicon dioxide or amorphous silicon.

3. The method of claim 2, wherein the formation of the POI substrate further comprises forming a trapping layer, the trapping layer being interposed between the intermediate stack and the front face, the trapping layer configured to limit the mean free path of electric carriers at the interface formed between the intermediate stack and the trapping layer with respect to the mean free path of electric carriers at an interface formed between the intermediate stack and the support substrate.

4. The method of claim 3, wherein the trapping layer has a defect density greater than a predetermined defect density, the predetermined defect density being a defect density for which resistivity of the trapping layer is greater than or equal to 10 Kilo-ohm for temperatures between −20° C. and 120° C.

5. The method of claim 4, wherein the trapping layer comprises at least one of the following materials: amorphous silicon, polycrystalline silicon.

6. The method of claim 2, wherein the forming of the intermediate stack comprises forming the third layer on the main face prior to carrying out the implanting of the species in the donor substrate.

7. The method of claim 6, wherein the forming of the intermediate stack comprises forming the first layer and the second layer on the front face so that assembling of the useful layer with the front face of the support substrate comprises placing the second layer in contact with the third layer.

8. The of claim 2, further comprising forming the third layer to have a thickness between 10 nm and 100 nm.

9. The method of claim 1, wherein the method comprises a preliminary step, carried out prior to step a), and during which the donor substrate is subjected to a vapor-phase oxygen treatment so as to reduce or limit effects of pyroelectricity in the donor substrate, and consequently in the useful layer, when subjected to a rise in temperature.

10. The method of claim 1, wherein the donor substrate comprises iron-doped lithium tantalate, the iron doping being between 0.001% and 0.05% by weight percentage.

11. The method of claim 1, further comprising forming the first layer to have a thickness of between 100 nm and 1000 nm, and forming the second layer to have a thickness of between 100 nm and 200 nm.

12. The method of claim 1, wherein the method comprises forming at least one electroacoustic transducer on and/or in the useful layer.

13. The method of claim 1, wherein the support substrate comprises at least one of the elements chosen from: a silicon substrate with orientation (110), a quartz substrate with orientation (YX/t)/θ/90° with θ between −20° and 60°.

14. The method of claim 1, wherein the LiTaO₃ has a (YX)/θ orientation with θ between 10° and 52°.

15. The method of claim 10, wherein the donor substrate comprises iron-doped lithium tantalate, the iron doping being between 0.002% and 0.01% by weight percentage.

16. The method of claim 11, further comprising forming the first layer to have a thickness of between 300 nm and 600 nm.

17. The method of claim 13, wherein the support substrate comprises at least one of the elements chosen from: a silicon substrate with orientation (110), a quartz substrate with orientation (YX/t)/θ/90° with θ between 10° and 30°.

18. The method of claim 14, wherein the LiTaO₃ has a (YX)/θ orientation with θ between 15° and 30°.

19. A method of manufacturing an elastic wave device configured to operate at a frequency below 1 GHz, comprising:
implanting species in a donor substrate comprising LiTaO₃ to form a layer comprising an embrittlement zone in a volume of the donor substrate, the embrittlement zone delimiting, with a main face of the donor substrate, a useful layer;
transferring the useful layer onto a front face of a support substrate, the transferring comprising, assembling the donor substrate and the support substrate, and then heat treating the assembled donor substrate and support substrate and initiating a fracture wave along the embrittlement zone to transfer the useful layer onto the support substrate;
wherein the method comprises forming an intermediate stack between a front face of the support substrate and the useful layer, the intermediate stack comprising a layer of silicon dioxide adjacent the front face and a layer comprising silicon nitride, alumina or aluminum nitride adjacent the useful layer.
